(19) United States
(12) Patent Application Publication
(10) Pub. No.: US 2026/0050056 A1
(43) Pub. Date: Feb. 19, 2026

(54) MAGNETIC RESONANCE IMAGE GENERATION METHOD AND APPARATUS, AND MAGNETIC RESONANCE IMAGING SYSTEM

(71) Applicant: GE Precision Healthcare LLC, Waukesha, WI (US)

(72) Inventors: Lei Gao, Beijing (CN); Hua Li, Beijing (CN)

(21) Appl. No.: 19/301,191

(22) Filed: Aug. 15, 2025

(30) Foreign Application Priority Data
Aug. 15, 2024 (CN) 202411121813.6

(51) Int. Cl. G01R 33/561; G01R 33/48; G01R 33/563

(52) U.S. Cl. CPC G01R 33/5616; G01R 33/4828; G01R 33/56341

(57) ABSTRACT

A magnetic resonance image generation method, apparatus, and imaging system are provided. The method includes acquiring at least two data sets using two or more pulse sequence groups with offset data acquisition windows, generating reconstructed images from each data set, and synthesizing at least two of the reconstructed images to produce a magnetic resonance image. This approach reduces or suppresses fat artifacts in magnetic resonance images.

### CROSS REFERENCE TO RELATED APPLICATIONS

The present application claims priority and benefit of Chinese Patent Application No. 202411121813.6 filed on Aug. 15, 2024, which is incorporated herein by reference in its entirety.

### TECHNICAL FIELD

Embodiments of the present application relate to the technical field of medical devices, and relate in particular to a magnetic resonance image generation method and apparatus, and a magnetic resonance imaging system.

### BACKGROUND

Magnetic resonance (MR) imaging systems are widely used in the field of medical diagnosis. A magnetic resonance system generally has a main magnet, a gradient amplifier, a radio-frequency amplifier, a gradient coil, a transmit chain module, a transmit/receive coil, a receive chain module, etc. The transmit chain module generates a pulse signal and transmits the same to the transmit/receive coil; the transmit/receive coil generates a radio-frequency excitation signal to excite a scanned subject to generate a magnetic resonance signal; and after the excitation ends, by means of spatial encoding, the transmit/receive coil acquires the magnetic resonance signal, and fills the magnetic resonance signal into a k-space so that a medical image is reconstructed.

Echo planar imaging (EPI) is a fast magnetic resonance imaging method. Hydrogen (H) protons from fat and H protons from water have different electron environments around them, and thus there is a difference in resonance frequency between the two, resulting in generation of fat artifacts in magnetic resonance images.

In the EPI method, some techniques can be used to suppress fat artifacts, such as: chemical shift saturation, slice-selective gradient reversal, short tau inversion recovery (STIR), and spectral-spatial water excitation. Fat artifacts can be reliably suppressed by a combination of two or more of the above techniques.

In some scenarios, some of the techniques described above cannot be used due to the limitation of minimum slice thickness or radio-frequency (RF) pulse bandwidth, and thus it is difficult to suppress fat artifacts, resulting in residual fat artifacts in magnetic resonance images. Accordingly, there is a need for improved imaging techniques.

### SUMMARY

In the embodiments of the present application a magnetic resonance image generation method and apparatus, and a magnetic resonance imaging system are provided. Data sets are acquired by offsetting data acquisition windows of different pulse sequence groups in time, and reconstructed images generated from the data sets are synthesized, so that image components generated by fat in the reconstructed images can be canceled out, thereby acquiring a magnetic resonance image in which fat artifacts are suppressed.

In accordance with an embodiment of the present technique, a method for generating a magnetic resonance image is provided. The method includes acquiring at least two data sets using two or more pulse sequence groups, where the data acquisition windows of the respective groups are offset in time. The method further includes generating reconstructed images from each data set and synthesizing at least two of these reconstructed images to obtain the magnetic resonance image.

In accordance with another embodiment of the present technique, a magnetic resonance image generation apparatus is provided. The apparatus includes a data acquisition unit configured to obtain at least two data sets using two or more pulse sequence groups, where the data acquisition windows of the respective groups are offset in time. It further includes an image reconstruction unit for generating reconstructed images from each data set, and an image synthesis unit for combining at least two of the reconstructed images to produce a magnetic resonance image.

In accordance with yet another embodiment of the present technique, a magnetic resonance imaging system is provided. The system includes a gradient coil for generating gradient pulses and a radio-frequency coil for generating RF pulses. A processor is connected to these coils and configured to control them to form at least two pulse sequence groups with offset data acquisition windows, acquire corresponding data sets, generate reconstructed images from each data set, and synthesize at least two of the reconstructed images to produce a magnetic resonance image.

One of the beneficial effects of the examples of the present application is that: Data sets are acquired by offsetting data acquisition windows of different pulse sequence groups in time, and reconstructed images generated from the data sets are synthesized, so that image components generated by fat in the reconstructed images can be canceled out, thereby acquiring a magnetic resonance image in which fat artifacts are suppressed.

With reference to the following description and drawings, specific embodiments of the examples of the present application are disclosed in detail, and the means by which the principles of the examples of the present application can be employed are illustrated. It should be understood that the embodiments of the present application are therefore not limited in scope. Within the scope of the spirit and clauses of the appended claims, the embodiments of the present application include many changes, modifications, and equivalents.

### BRIEF DESCRIPTION OF THE DRAWINGS

The included drawings are used to provide further understanding of the examples of the present application, which constitute a part of the description and are used to illustrate the embodiments of the present application and explain the principles of the present application together with textual description. Evidently, the drawings in the following description are merely some examples of the present application, and a person of ordinary skill in the art may obtain other embodiments according to the drawings without involving inventive skill. In the drawings:

FIG. 1 is a schematic diagram of a magnetic resonance imaging system according to an embodiment of the present application;

FIG. 2 is a schematic diagram of a magnetic resonance image generation method according to an embodiment of the present application;

FIG. 3 is a schematic diagram of a first pulse sequence group in Example 1;

FIG. 4 is a schematic diagram of a second pulse sequence group in Example 1;

FIG. 5 is a schematic diagram of a third pulse sequence group in Example 1;

FIG. 6 is a schematic diagram of a first pulse sequence group in Example 2;

FIG. 7 is a schematic diagram of a second pulse sequence group in Example 2;

FIG. 8 is a schematic diagram of a third pulse sequence group in Example 2;

FIG. 9 is a schematic diagram of reconstructed images and magnetic resonance images obtained by applying embodiments of the present application to EPI methods;

FIG. 10 is a schematic diagram of a magnetic resonance image generation apparatus according to an embodiment of the present application; and

FIG. 11 is a schematic diagram of a magnetic resonance image generation apparatus according to an embodiment of the present application.

### DETAILED DESCRIPTION

The foregoing and other features of the examples of the present application will become apparent from the following description and with reference to the drawings. In the description and drawings, specific embodiments of the present application are disclosed in detail, and part of the embodiments in which the principles of the examples of the present application may be employed are indicated. It should be understood that the present application is not limited to the described embodiments. On the contrary, the examples of the present application include all modifications, variations, and equivalents which fall within the scope of the appended claims.

In the embodiments of the present application, the terms “first” and “second” etc., are used to distinguish different elements, but do not represent a spatial arrangement or temporal order, etc., of these elements, and these elements should not be limited by these terms. The term “and/or” includes any and all combinations of one or more associated listed terms. The terms “comprise”, “include”, “have”, etc., refer to the presence of described features, elements, components, or assemblies, but do not exclude the presence or addition of one or more other features, elements, components, or assemblies.

In the embodiments of the present application, the singular forms “a” and “the”, etc., include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ” and the term “on the basis of” should be construed as “at least in part on the basis of . . . ”, unless otherwise specified in the context.

In the embodiments of the present application, the term “scanned subject” may be equivalently replaced with “subject”, “subject to be scanned”, “subject being scanned”, “patient”, “subject of study”, or the like, and the “scanned subject” may be a living being such as a human being or an animal, or an inanimate object.

In the embodiments of the present application, the term “include/comprise” when used herein refers to the presence of features, integrated components, operations, or assemblies, but does not preclude the presence or addition of one or more other features, integrated components, operations, or assemblies.

The features described and/or illustrated for one implementation may be used in one or more other implementations in the same or similar manner, be combined with features in other embodiments, or replace features in other implementations.

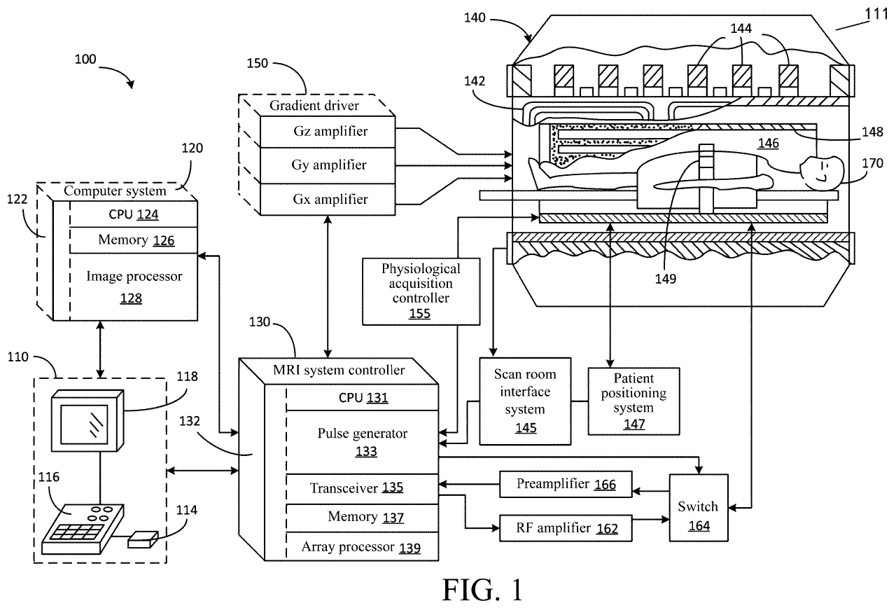

For ease of understanding, FIG. 1 shows a magnetic resonance imaging (MRI) system 100 according to some embodiments of the present application.

As shown in FIG. 1, the MRI system 100 includes a scanning unit 111. The scanning unit 111 is used to perform a magnetic resonance scan of a subject (e.g., a human body) 170 to generate image data of a region of interest of the subject 170, wherein the region of interest may be a pre-determined anatomical site or anatomical tissue.

The operation of the MRI system 100 is controlled by an operator workstation 110 that includes an input device 114, a control panel 116, and a display 118. The input apparatus 114 may be a joystick, a keyboard, a mouse, a trackball, a touch-activated screen, voice control, or any similar or equivalent input apparatus. The control panel 116 may include a keyboard, a touch-activated screen, voice control, a button, a slider, or any similar or equivalent control apparatus. The operator workstation 110 is coupled to and in communication with a computer system 120 that enables an operator to control the generation and display of images on the display 118. The computer system 120 includes various components that communicate with one another via an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced by medical imaging functions implemented in the CPU 124. The computer system 120 may be connected to an archive media apparatus, a persistent or backup memory, or a network. The computer system 120 may be coupled to and communicates with a separate MRI system controller 130.

The MRI system controller 130 includes a set of components that communicate with one another via an electrical and/or data connection module 132. The connection module 132 may employ a direct wired connection, a fiber optic connection, a wireless communication link, etc. The MRI system controller 130 may include a CPU 131, a sequence pulse generator (also known as pulse generator) 133 in communication with the operator workstation 110, a calibration module 134 configured to calibrate a medical imaging system, a transceiver (also known as RF transceiver) 135, a memory 137, and an array processor 139.

In some embodiments, the sequence pulse generator 133 may be integrated into a resonance assembly 140 of the scanning unit 111 of the MRI system 100. The MRI system controller 130 may receive a command from the operator workstation 110, and is coupled to the scanning unit 111 to indicate an MRI scanning sequence to be performed during an MRI scan, so as to be used to control the scanning unit 111 to perform the flow of the aforementioned magnetic resonance scan. The MRI system controller 130 is further coupled to a gradient driver system (also known as gradient driver) 150 and is in communication therewith, and the gradient driver system is coupled to a gradient coil assembly 142 to generate a magnetic field gradient during an MRI scan.

The sequence pulse generator 133 may further receive data from a physiological acquisition controller 155 that receives signals from a plurality of different sensors (e.g., electrocardiogram (ECG) signals from electrodes attached to a patient, etc.), the sensors being connected to a subject or patient 170 undergoing an MRI scan. The sequence pulse generator 133 is coupled to and in communication with a scan room interface system 145 that receives signals from various sensors associated with the state of the resonance assembly 140. The scan room interface system 145 is further coupled to a patient positioning system 147 and is in communication therewith, and the patient positioning system 147 sends and receives signals to control a patient table (e.g., an examination table) to move to a desired position for an MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the G_{y}, G_{y}, and G_{z} amplifiers excites a corresponding gradient coil in the gradient coil assembly 142, so as to generate a magnetic field gradient used to spatially encode an MR signal during an MRI scan. The gradient coil assembly 142 is disposed within the resonance assembly 140, and the resonance assembly further includes a superconducting magnet having a superconducting coil 144 that, in operation, provides a static uniform longitudinal magnetic field B₀ throughout a cylindrical imaging volume 146. The resonance assembly 140 further includes an RF body coil 148, which, in operation, provides a transverse magnetic field B₁, and the transverse magnetic field B₁ is substantially perpendicular to B₀ throughout the entire cylindrical imaging volume 146. The resonance assembly 140 may further include an RF surface coil 149 for imaging different anatomical structures of the patient undergoing the MRI scan. The RF body coil 148 and the RF surface coil 149 may be configured to operate in a transmit and receive mode, a transmit mode, or a receive mode.

The x direction may also be referred to as a frequency encoding direction or a kx direction in the k-space, the y direction may be referred to as a phase encoding direction or a ky direction in the k-space, and the z direction may be referred to as a layer surface (slice) selection (layer selection) direction or layer direction. Gₓ can be used for frequency encoding or signal readout or data readout, and is generally referred to as a frequency encoding gradient or a readout gradient. G_{y} can be used for phase encoding, and is generally referred to as a phase encoding gradient. G_{z} can be used for slice (layer, or layer surface) position selection to acquire k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses amplified by an RF amplifier 162, and provides the same to the RF body coil 148 through a transmit/receive switch (also known as T/R switch or switch) 164.

As described above, the RF body coil 148 and the RF surface coil 149 may be used to transmit RF excitation pulses and/or receive resulting MR signals from the patient undergoing the MRI scan. The MR signals emitted by excited nuclei in the patient of the MRI scan may be sensed and received by the RF body coil 148 or the RF surface coil 149 and sent back to a preamplifier 166 through the T/R switch 164. The T/R switch 164 may be controlled by a signal from the sequence pulse generator 133 to electrically connect the RF amplifier 162 to the RF body coil 148 in the transmit mode and to connect the preamplifier 166 to the RF body coil 148 in the receive mode. The T/R switch 164 may further enable the RF surface coil 149 to be used in the transmit mode or the receive mode.

In some embodiments, the MR signals sensed and received by the RF body coil 148 or the RF surface coil 149 and amplified by the preamplifier 166 are stored in the memory 137 for post-processing as a raw k-space data array. A reconstructed magnetic resonance image can be obtained by transforming/processing the stored raw k-space data.

In some embodiments, the MR signals sensed and received by the RF body coil 148 or the RF surface coil 149 and amplified by the preamplifier 166 are demodulated, filtered, and digitized in a receiving portion of the transceiver 135, and transmitted to the memory 137 in the MRI system controller 130. For each image to be reconstructed, the data is rearranged into separate k-space data arrays, and each of said separate k-space data arrays is input into the array processor 139, and the array processor is operated to transform the data into an array of image data by Fourier transform.

The array processor 139 uses transform methods, most commonly Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 1 is intended for illustration. Suitable MRI systems may include more, fewer, and/or different components.

The MRI system controller 130 and the image processor 128 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, medical imaging, etc. For example, the storage medium may store a program used to implement the magnetic resonance imaging method according to the embodiments of the present application. The described storage medium may include, for example, a ROM, a floppy disk, a hard disk, an optical disk, a magneto-optical disk, a CD-ROM, or a non-volatile memory card.

The aforementioned “imaging sequence” (also referred to below as a scanning sequence or a pulse sequence) refers to a combination of pulses having specific amplitudes, widths, directions, and time sequences and applied when a magnetic resonance imaging scan is executed. These pulses may typically include, for example, radio-frequency pulses and gradient pulses. The radio-frequency pulses may include, for example, radio-frequency excitation pulses, radio-frequency refocusing pulses, inverse recovery pulses, etc. The gradient pulses may include, for example, the aforementioned gradient pulse used for layer selection (such as), gradient pulse used for phase encoding, gradient pulse used for frequency encoding, gradient pulse used for phase shifting (phase shift), gradient pulse used for dispersion of phases (dephasing), etc.

Typically, a plurality of scan sequences can be preset in the magnetic resonance system, so that the sequence suitable for clinical detection requirements can be selected. The clinical detection requirements may include, for example, an imaging site, an imaging function, an imaging effect, and the like.

In addition, the aforementioned gradient field can be considered as being oriented both in a physical plane and by the logical axis. In a physical sense, these fields are oriented orthogonally to each other to form a coordinate system, and the coordinate system can be rotated by appropriately manipulating a pulse current applied to an individual gradient field coil.

Thanks to the gradient system, magnetic resonance imaging can be implemented in any direction. Conventional anatomical sites may be scanned using conventional orthoaxial (tri-azimuthal) scans: transverse (TRA) or axial (AX), sagittal (SAG), and coronal (COR) scans. Some special complex sites may be scanned using an oblique scan, for example, a short-axis, four-chamber view is used for a cardiac scan.

For example, in an orthoaxial scan, a physical gradient generated by a gradient amplifier can be configured with respect to an imaging system, so that a physical axis aligns/coincides with the logical axis when imaging is performed in an axial reference plane, a sagittal reference plane, and a coronal reference plane. For example, for axial imaging, coronal imaging, or sagittal imaging, the G_{z} amplifier can be configured to generate a slice selection gradient, the G_{y} amplifier can be configured to generate a phase-encoding gradient, and the Gₓ amplifier can be configured to generate a frequency-encoding gradient.

For another example, when an oblique scan is performed, the logical axis-based coordinate system is rotated by a certain angle relative to the physical axis-based coordinate system. In this case, the slice selection gradient, the frequency-encoding gradient, and the phase-encoding gradient need to be defined in the logical axis-based coordinate system. The slice selection gradient determines a slice of tissue or anatomical structure to be imaged in a patient. Therefore, a slice selection gradient field can be applied simultaneously with a selective radio frequency excitation pulse to excite spin volumes in oblique slices precessing at the same frequency. A slice thickness is determined by a bandwidth of the radio frequency excitation pulse and gradient strength in an entire field of view.

The technical solution of the present application is described below with reference to the embodiments.

Provided in an embodiment of the present application is a method for adjusting a scanning sequence for a magnetic resonance imaging system.

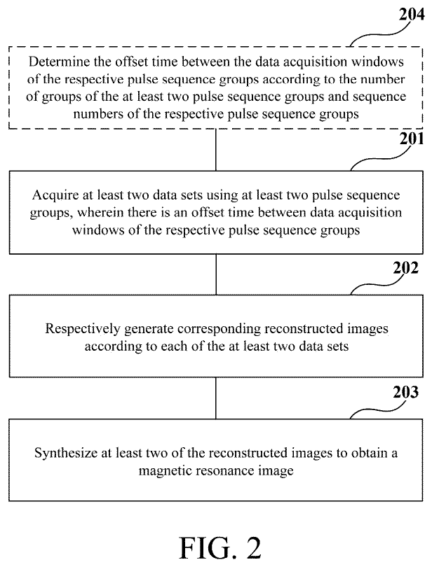

FIG. 2 illustrates a magnetic resonance image generation method according to an embodiment of the present application. The method includes step 201, which involves acquiring at least two data sets using two or more pulse sequence groups, where the data acquisition windows of the respective groups are offset in time. Step 202 includes generating corresponding reconstructed images from each of the data sets, and step 203 includes synthesizing at least two of these reconstructed images to obtain a magnetic resonance image.

According to the above-described embodiment, data sets are acquired by offsetting data acquisition windows of different pulse sequence groups in time, and reconstructed images generated from the data sets are synthesized, so that image components generated by fat in the reconstructed images can be canceled out, thereby acquiring a magnetic resonance image in which fat artifacts are suppressed. In addition, the present application not only can be used to suppress fat artifacts but can also be used to suppress artifacts generated by other substances having different resonance frequencies from that of water, for example, to suppress artifacts generated by substances such as silicon oil and silicone gel.

The above-described embodiment of the present application is applicable to an echo planar imaging (EPI) method, for example, a diffusion-weight echo planar imaging (DW EPI) method, a multi-direction diffusion-weight echo planar imaging (multi-direction DW EPI) method, a gradient echo pulse sequence echo planar imaging (GRE EPI) method, or the like. Furthermore, the above-described embodiment of the present application may also be used in other magnetic resonance imaging methods.

In some embodiments, in operation 201, pulse sequences for an MRI system may be acquired in various ways. For example, the pulse sequences may be prestored, or may be generated according to actual situations.

The pulse sequences may be determined according to a preset scanning protocol, and at least includes radio-frequency pulses and gradient pulses.

The gradient pulses may include a first gradient pulse that may include a gradient pulse for phase encoding. The first gradient pulses may be applied in a first direction which is, for example, the aforementioned x-direction.

The gradient pulses may further include at least one of a second gradient pulse and a third gradient pulse which are applied in a direction different from that of the first gradient pulse, where the second gradient pulse may include a gradient pulse for frequency encoding, and the third gradient pulse may include a gradient pulse for layer selection. For example, the second gradient pulse may be applied in a second direction which is, for example, the aforementioned y-direction; and the third gradient pulse may be applied in a third direction which is, for example, the aforementioned z-direction.

In some embodiments, the pulse sequences may include a gradient echo (GRE) pulse sequence, a fast spin echo (FSE) pulse sequence, a fast balanced steady-state free precession (hSSFP) sequence, and the like, but the embodiments of the present application are not limited thereto.

In some embodiments, each pulse sequence group may have its own data acquisition window, and the data acquisition window may be a section of time window for data acquisition. In the data acquisition window, there is an encoding gradient pulse sequence. The encoding gradient pulse sequence may have at least two among the first gradient pulse, the second gradient pulse, and the third gradient pulse, so that in the data acquisition window, encoding may be performed using at least two among the first gradient pulse, the second gradient pulse and the third gradient pulse; for example, phase encoding is performed using the first gradient pulse, frequency encoding is performed using the second gradient pulse, and layer selection encoding is performed using the third gradient pulse. Encoded data is acquired and stored to form data sets, where one pulse sequence group may correspond to one data set. Thus, each pulse sequence group may correspond to its own data set, and data in one data set may be used to generate a corresponding reconstructed image.

In some examples of operation 201, in the data acquisition window of each pulse sequence group, at least two among the first gradient pulse, the second gradient pulse, and the third gradient pulse may be used to excite corresponding gradient coils in the gradient coil assembly 142 to generate a magnetic field gradient for spatially encoding MR signals during an MRI scan, and the MR signals spatially encoded by the magnetic field gradient are sensed and received by the RF body coil 148 or the RF surface coil 149 and amplified by the preamplifier 166, demodulated, filtered, and digitized in the receiving portion of the transceiver 135, and transmitted to the memory 137 in the MRI system controller 130. The data sets stored in the memory 137 may correspond to the respective pulse sequence groups, respectively.

In operation 201, there is an offset time between the data acquisition windows of the respective pulse sequence groups, for example, an offset time is present between the start times of the data acquisition windows of the respective pulse sequence groups.

In some examples, the number of pulse sequence groups is, for example, n (n is a natural number greater than or equal to 2), and in the n pulse sequence groups, there is an offset time between the data acquisition window of an i-th pulse sequence group (i is a natural number and 1≤i≤n) and the data acquisition window of each of the other n−1 pulse sequence groups. For example, there is an offset time between the start time of the data acquisition window of the i-th pulse sequence group and the start time of the data acquisition window of each of the other n−1 pulse sequence groups.

Furthermore, it should be noted that in the following description of the present application, the start time of the data acquisition window of an (i+1)-th pulse sequence group is later than the start time of the data acquisition window of the i-th pulse sequence group.

In operation 202, according to data sets respectively corresponding to the pulse sequence groups, corresponding reconstructed images are respectively generated. For example, for n pulse sequence groups, n reconstructed images can be generated. In some examples, data in the data sets is filled into a K-space to generate the reconstructed images. For a specific method for generating a reconstructed image, reference may be made to the related art, which is not further described in detail in the present application.

In operation 203, a plurality of reconstructed images are synthesized to obtain a magnetic resonance image. For example, n reconstructed images are synthesized to obtain a magnetic resonance image.

In some embodiments of operation 203, magnitudes of at least two reconstructed images may be averaged for synthesis, so as to generate a magnetic resonance image. For example, for n reconstructed images, amplitude information of each pixel unit (e.g., each pixel unit may include one or more pixels) in each reconstructed image is extracted, and amplitude information of pixel units at the same position in the n reconstructed images is averaged to obtain a magnetic resonance image, where the average value obtained by the averaging is, for example, an arithmetic average value, a geometric average value, a weighted average value, or other types of average values.

In the present application, through operation 201, there is an offset time between the data acquisition windows of different pulse sequence groups, so that data sets in which MR signals of fat molecules and MR signals of water molecules in different vibration states are superimposed can be obtained, respectively. In operation 202, on the basis of the data sets obtained in operation 201, reconstructed images respectively corresponding to the data sets are respectively formed, so that the reconstructed images have fat artifacts corresponding to fat molecules in different vibration states, respectively; In operation 203, a plurality of reconstructed images are synthesized such that the fat artifacts in different states in the images are canceled out, thereby generating a magnetic resonance image in which the fat artifacts are suppressed.

In some embodiments, as shown in FIG. 2, the magnetic resonance image generation method may further include step 204, which involves determining the offset time between the data acquisition windows of the respective pulse sequence groups based on the number of pulse sequence groups and their sequence numbers.

In some embodiments of operation 204, the offset time between the data acquisition windows of two pulse sequence groups with adjacent sequence numbers is inversely proportional to the number of groups. For example, the number of pulse sequence groups is n (n is a natural number greater than or equal to 2), and in the n pulse sequence groups, the offset time between the data acquisition window of an i-th pulse sequence group (i is a natural number, and 1≤i≤ n) and the data acquisition window of an (i−1)-th or (i+1)-th pulse sequence group is inversely proportional to the number of groups n, that is, the greater the number of groups n, the shorter the offset time.

In some embodiments of operation 204, the offset time between the data acquisition window of a pulse sequence with a sequence number of i and the data acquisition window of a pulse sequence with a sequence number of j is proportional to i-j, where i and j are natural numbers greater than or equal to 1, and i is greater than j. For example, the number of pulse sequence groups is n (n is a natural number greater than or equal to 2), and in the n pulse sequence groups, the offset time between the data acquisition window of the i-th pulse sequence group (i is a natural number, and 1≤i≤n) and the data acquisition window of the j-th pulse sequence group (j is a natural number, and 1≤j≤n and j≤i) is proportional to i-j and inversely proportional to the number of groups n.

In some examples of operation 204, the offset time TE_{iNEX} of the i-th pulse sequence group among the n pulse sequence groups with respect to the first pulse sequence group may be calculated using Formula (1) below.

$${TE}_{iNEX} = inPhaseTe * \frac{i - 1}{n} = \frac{1}{\frac{γ}{2 π} * B * ChemShift} * \frac{i - 1}{n} , \qquad ( 1 )$$

where inPhaseTe represents the water/fat in-phase echo time; ChemShift represents a chemical shift of fat with respect to water; B represents the magnitude of the aforementioned static uniform longitudinal magnetic field

$${B}_{0} ; \frac{γ}{2 π} = 42.58 MHz / T ,$$

and γ represents a gyromagnetic ratio.

In addition, if the present application is used to suppress artifacts caused by a substance having a resonance frequency different from that of water, inPhaseTe of Formula (1) may represent the in-phase echo time of water and the other substance, and ChemShift represents a chemical shift of the other substance with respect to water.

Table 1 shows some examples of the offset time TE_{iNEX} of the i-th pulse sequence group with respect to the first pulse sequence group when n calculated according to Formula (1) has different values. In the examples shown in Table 1, B=1.5 T (tesla).

TABLE 1

| | | i = 1 | i = 2 | i = 3 | i = 4 | i = 5 | i = 6 | i = 7 |
|---|---|---|---|---|---|---|---|---|
| n = 2 | TE_{iNEX} | 0 | 2.237212 | | | | | |
| n = 3 | TE_{iNEX} | 0 | 1.491474 | 2.982949 | | | | |
| n = 4 | TE_{iNEX} | 0 | 1.118606 | 2.237212 | 3.355817 | | | |
| n = 5 | TE_{iNEX} | 0 | 0.894885 | 1.789769 | 2.684654 | 3.579538 | | |
| n = 6 | TE_{iNEX} | 0 | 0.745737 | 1.491474 | 2.237212 | 2.982949 | 3.728686 | |
| n = 7 | TE_{iNEX} | 0 | 0.639203 | 1.278407 | 1.91761 | 2.556813 | 3.196016 | 3.83522 |

For example, in Table (1), when n=3: for i=2, the offset time TENEx of a second pulse sequence group with respect to the first pulse sequence group is 1.491474; and for i=3, the offset time TE_{iNEX} of a third pulse sequence group with respect to the first pulse sequence group is 2.982949.

In some embodiments of the present application, the at least two pulse sequence groups have identical excitation conditions, for example, the excitation conditions of n pulse sequence groups are identical, and thus the magnetic resonance image generation method may be referred to as a magnetic resonance imaging method based on a plurality of excitations, for example, a multiple number-of-excitations echo planar imaging (multiple NEX EPI) method, where the echo planar imaging method may be: a multiple NEX diffusion-weight echo planar imaging (DW EPI) method, a gradient echo pulse sequence echo planar imaging (GRE EPI) method, or the like.

In some other embodiments of the present application, the excitation conditions of the at least two pulse sequence groups are different, for example, the directions of diffusion gradients of the at least two pulse sequence groups are different from each other, and thus the magnetic resonance image generation method may be referred to as a multi-direction-based magnetic resonance imaging method, for example, a multi-direction diffusion-weight echo planar imaging (multi-direction DW EPI) method.

The at least two pulse sequence groups according to the present application will be described below with reference to specific examples.

### Example 1

In Example 1, at least two pulse sequence groups have identical excitation conditions, where the number of groups n of the at least two pulse sequence groups is 3, and the three pulse sequence groups are a first pulse sequence group, a second pulse sequence group, and a third pulse sequence group, respectively.

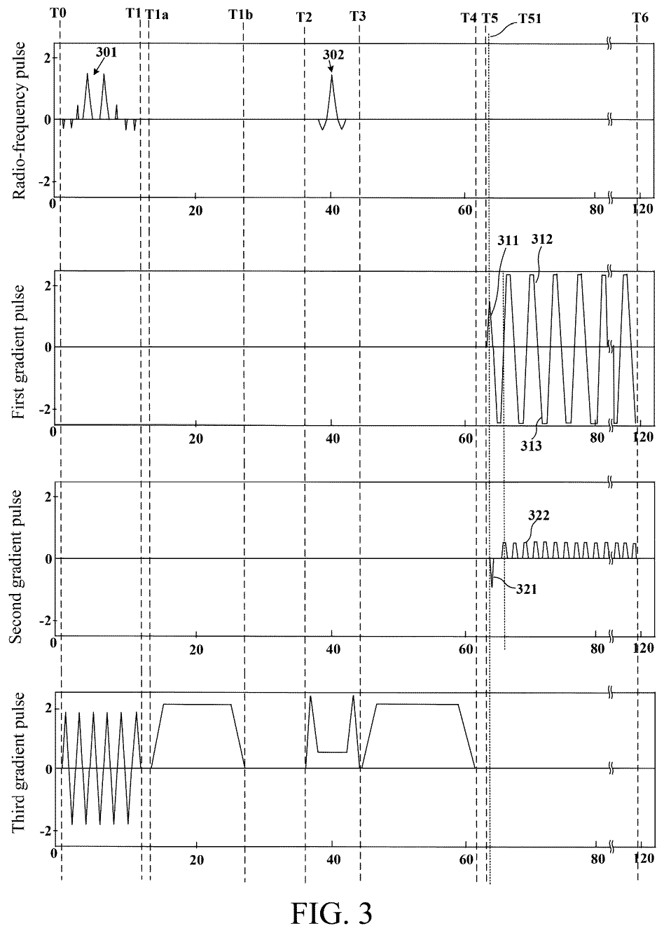

FIG. 3 is a schematic diagram of the first pulse sequence group in Example 1. FIG. 3 shows respective timing diagrams of a radio-frequency (RF) pulse, a first gradient pulse (e.g., x-direction), a second gradient pulse (e.g., y-direction), and a third gradient pulse (e.g., z-direction) in the first pulse sequence group, respectively. In each of the timing diagrams, the horizontal axis represents the time (unit: millisecond), and the vertical axis represents the amplitude of a pulse, where the radio-frequency pulse may be generated by the RF body coil 148 or the RF surface coil 149; and the first, second, and third gradient pulses may be generated by the gradient driver system 150, and are used to drive and excite corresponding gradient coils in the gradient coil assembly 142 to generate a corresponding magnetic field gradient.

In addition, for the description of the radio-frequency pulse, the first gradient pulse, the second gradient pulse and the third gradient pulse, reference may be made to the relevant explanations above regarding FIG. 1 and FIG. 2 in the present specification.

As shown in FIG. 3, there are a first radio-frequency pulse 301 (e.g., a 90-degree radio-frequency pulse) between T0 and T1, and a second radio-frequency pulse 302 (e.g., a 180-degree radio-frequency pulse) between T2 and T3, where the third gradient pulse is superimposed on both the first radio-frequency pulse 301 and the second radio-frequency pulse 302.

The third gradient pulse is present between T1a and T1b, and is used to apply a diffusion gradient in the third direction to diffuse water molecules. Furthermore, in some embodiments, the first gradient pulse, the second gradient pulse, and the third gradient pulse may also be applied between T1a and T1b.

The third gradient pulse is present between T3 and T4, and is used to apply a diffusion gradient in the third direction to diffuse water molecules. Furthermore, in some embodiments, the first gradient pulse, the second gradient pulse, and the third gradient pulse may also be applied between T3 and T4.

As shown in FIGS. 3, T5 to T6 is a data acquisition window of the first pulse sequence group. The first gradient pulse and the second gradient pulse are present between T5 and T6.

The first gradient pulse includes a positive-going triangular pulse 311, a positive-going trapezoidal pulse 312, and a negative-going trapezoidal pulse 313, and is used for phase encoding, where the start time of the positive-going triangular pulse 311 is T5.

The second gradient pulse includes a negative-going triangular pulse 321 and a positive-going trapezoidal pulse 322, where the negative-going triangular pulse 321 provides a pre-diffusion gradient, and the positive-going trapezoidal pulse 322 is used for frequency encoding. The start time of the negative-going triangular pulse 321 is T51.

The maximum amplitudes of the positive-going trapezoidal pulse 312 and the negative-going trapezoidal pulse 313 are greater than the maximum amplitude of the positive-going trapezoidal pulse 322. In the direction of the horizontal axis, the central time of each positive-going trapezoidal pulse 322 is the same as the time at which the amplitude of each positive-going trapezoidal pulse 312 is 0.

In FIG. 3, the pulse sequences in the period from T0 to T4 can provide a certain excitation condition for the MR scanning process. The period from T5 to T6 (i.e., data acquisition window) is used to encode the MR signals to obtain a data set for image reconstruction.

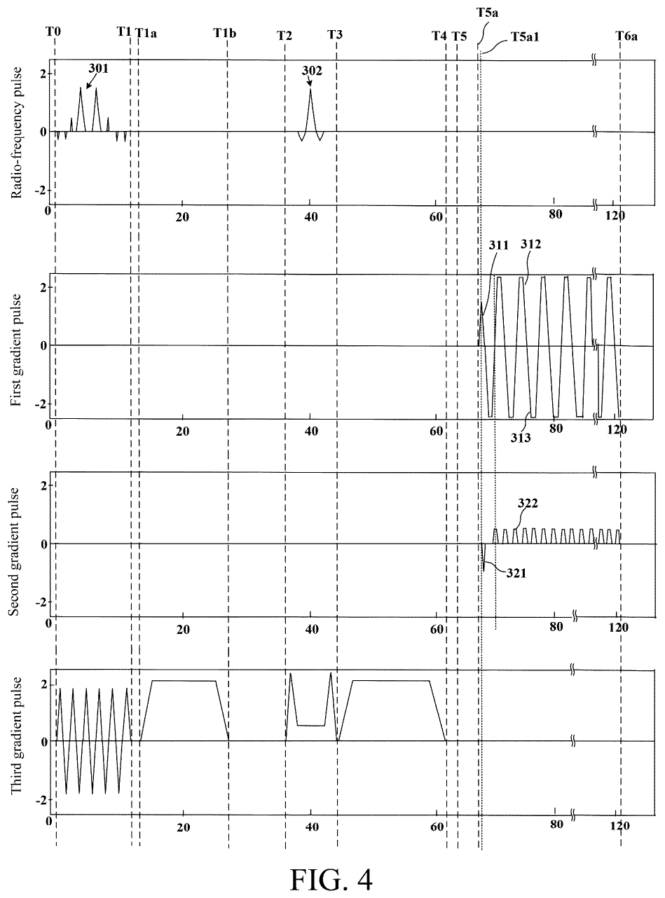

FIG. 4 is a schematic diagram of the second pulse sequence group in Example 1. In FIG. 4, the pulse sequences in the period from T0 to T4 are the same as those of FIG. 3, and thus the second pulse sequence group and the first pulse sequence group have identical excitation conditions.

In FIG. 4, T5a to T6a is a data acquisition window of the second pulse sequence group for encoding the MR signals to obtain a data set for image reconstruction. T5a has an offset time TE_{iNEX} with respect to T5, where i=2, so that the offset time is expressed as TE_{2NEX}, and the specific numerical value thereof can be calculated using Formula (1).

The first gradient pulse and the second gradient pulse are present between T5a and T6a.

The first gradient pulse includes a positive-going triangular pulse 311, a positive-going trapezoidal pulse 312, and a negative-going trapezoidal pulse 313, where the start time of the positive-going triangular pulse 311 is T5a.

The second gradient pulse includes a negative-going triangular pulse 321 and a positive-going trapezoidal pulse 322, where the start time of the negative-going triangular pulse 321 is T5a1.

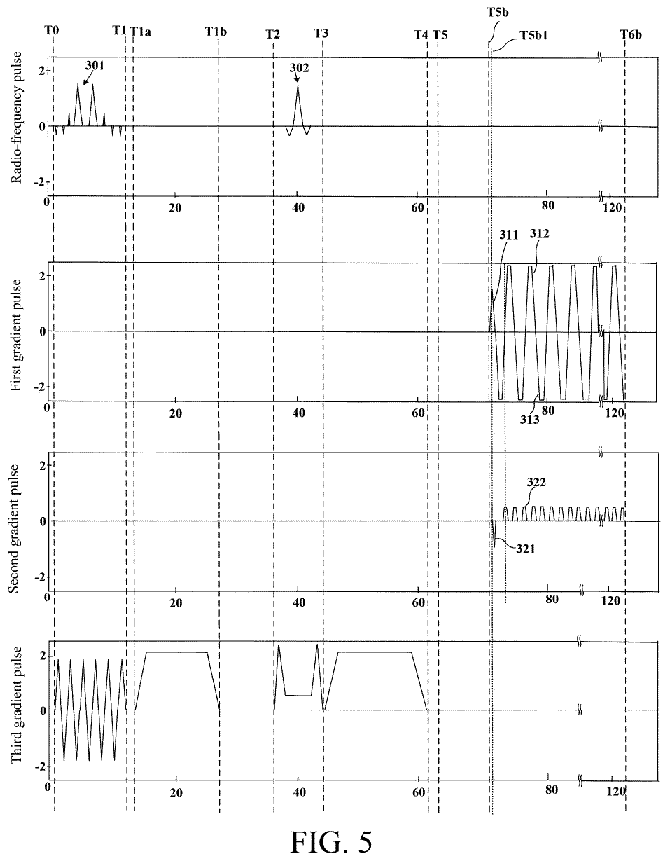

FIG. 5 is a schematic diagram of the third pulse sequence group in Example 1. In FIG. 5, the pulse sequences in the period from T0 to T4 are the same as those of FIG. 3, and thus the third pulse sequence group and the first pulse sequence group have identical excitation conditions.

In FIG. 5, T5b to T6b is a data acquisition window of the third pulse sequence group for encoding the MR signals to obtain a data set for image reconstruction. T5b has an offset time TE_{iNEX} with respect to T5, where i=3, so that the offset time is expressed as TE_{3NEX}, and the specific numerical value thereof can be calculated using Formula (1).

The first gradient pulse and the second gradient pulse are present between T5b and T6b.

The first gradient pulse includes a positive-going triangular pulse 311, a positive-going trapezoidal pulse 312, and a negative-going trapezoidal pulse 313, where the start time of the positive-going triangular pulse 311 is T5b.

The second gradient pulse includes a negative-going triangular pulse 321 and a positive-going trapezoidal pulse 322, where the start time of the negative-going triangular pulse 321 is T5b1.

Furthermore, in FIGS. 3, 4 and 5, after each data acquisition window, a positive-going triangular pulse serving as part of the second gradient pulse and a positive-going triangular pulse serving as part of the third gradient pulse may be further provided, so that the MR signals are sufficiently scattered to facilitate the next data acquisition.

### Example 2

In Example 2, at least two pulse sequence groups have excitation conditions different from each other, where the number of groups n of the at least two pulse sequence groups is 3, and the three pulse sequence groups are a first pulse sequence group, a second pulse sequence group, and a third pulse sequence group, respectively.

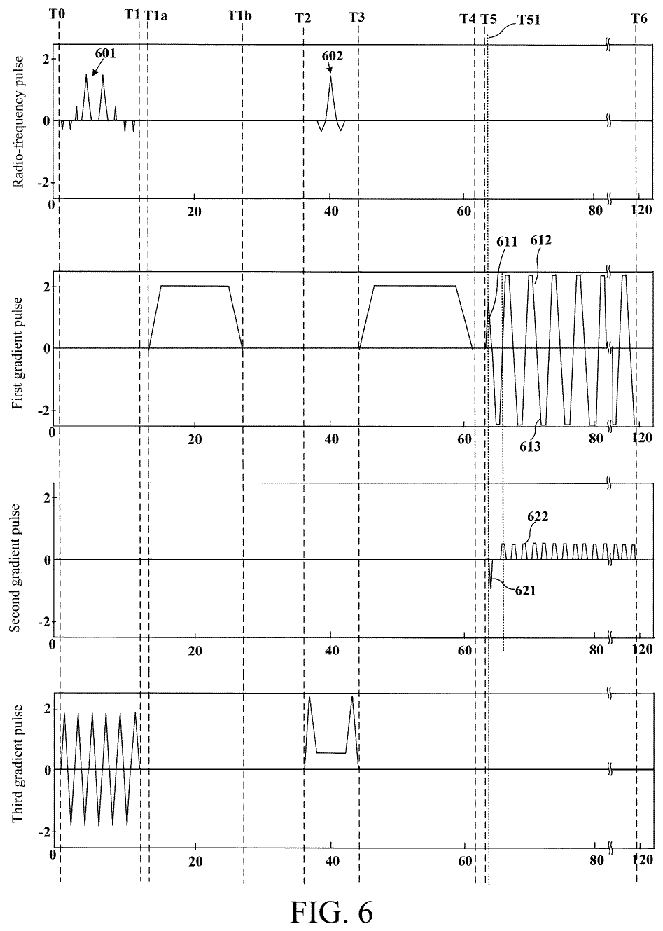

FIG. 6 is a schematic diagram of the first pulse sequence group in Example 2. FIG. 6 shows respective timing diagrams of a radio-frequency (RF) pulse, a first gradient pulse (e.g., x-direction), a second gradient pulse (e.g., y-direction), and a third gradient pulse (e.g., z-direction) in the first pulse sequence group, respectively. In each of the timing diagrams, the horizontal axis represents the time and the vertical axis represents the amplitude of a pulse.

For the description of the radio-frequency pulse, the first gradient pulse, the second gradient pulse and the third gradient pulse, reference may be made to the relevant explanations above regarding FIG. 1 and FIG. 2 in the present specification.

As shown in FIG. 6, there are a first radio-frequency pulse 601 (e.g., a 90-degree radio-frequency pulse) between T0 and T1, and a second radio-frequency pulse 602 (e.g., a 180-degree radio-frequency pulse) between T2 and T3, where the third gradient pulse is superimposed on both the first radio-frequency pulse 601 and the second radio-frequency pulse 602.

The first gradient pulse is present between T1a and T1b, and is used to apply a diffusion gradient in the first direction to diffuse water molecules.

The first gradient pulse is present between T1a and T1b, and is used to apply a diffusion gradient in the first direction to diffuse water molecules.

As shown in FIGS. 6, T5 to T6 is a data acquisition window of the first pulse sequence group. The first gradient pulse and the second gradient pulse are present between T5 and T6.

The first gradient pulse includes a positive-going triangular pulse 611, a positive-going trapezoidal pulse 612, and a negative-going trapezoidal pulse 613, and is used for phase encoding, where the start time of the positive-going triangular pulse 611 is T5.

The second gradient pulse includes a negative-going triangular pulse 621 and a positive-going trapezoidal pulse 622, where the negative-going triangular pulse 621 provides a pre-diffusion gradient, and the positive-going trapezoidal pulse 622 is used for frequency encoding. The start time of the negative-going triangular pulse 621 is T51.

The maximum amplitudes of the positive-going trapezoidal pulse 612 and the negative-going trapezoidal pulse 613 are greater than the maximum amplitude of the positive-going trapezoidal pulse 622. In the direction of the horizontal axis, the central time of each positive-going trapezoidal pulse 622 is the same as the time at which the amplitude of each positive-going trapezoidal pulse 612 is 0.

In FIG. 6, the pulse sequences in the period from T0 to T4 can provide a certain excitation condition for the MR scanning process, and in said excitation condition, the direction of the diffusion gradient is determined by the first gradient pulse. The period from T5 to T6 (i.e., data acquisition window) is used to encode the MR signals to obtain a data set for image reconstruction.

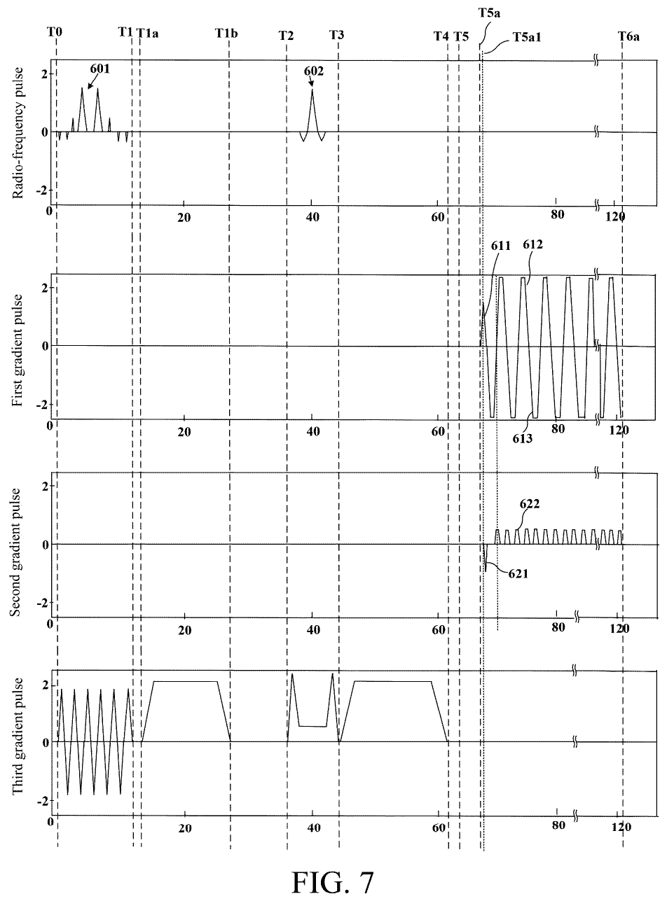

FIG. 7 is a schematic diagram of the second pulse sequence group in Example 2. In FIG. 7, the pulse sequences in the period from T0 to T4 differ from those of FIG. 6 in that: the third gradient pulse is provided between T1a and T1b and between T3 and T4, and is used to apply a diffusion gradient in the third direction to diffuse water molecules. Hence, the second pulse sequence group and the first pulse sequence group have different excitation conditions.

In FIG. 7, T5a to Toa is a data acquisition window of the second pulse sequence group for encoding the MR signals to obtain a data set for image reconstruction. T5a has an offset time TE_{iNEX} with respect to T5, where i=2, so that the offset time is expressed as TE_{2NEX}, and the specific numerical value thereof can be calculated using Formula (1).

The first gradient pulse and the second gradient pulse are present between T5a and T6a.

The first gradient pulse includes a positive-going triangular pulse 611, a positive-going trapezoidal pulse 612, and a negative-going trapezoidal pulse 613, where the start time of the positive-going triangular pulse 611 is T5a.

The second gradient pulse includes a negative-going triangular pulse 621 and a positive-going trapezoidal pulse 622, where the start time of the negative-going triangular pulse 621 is T5a1.

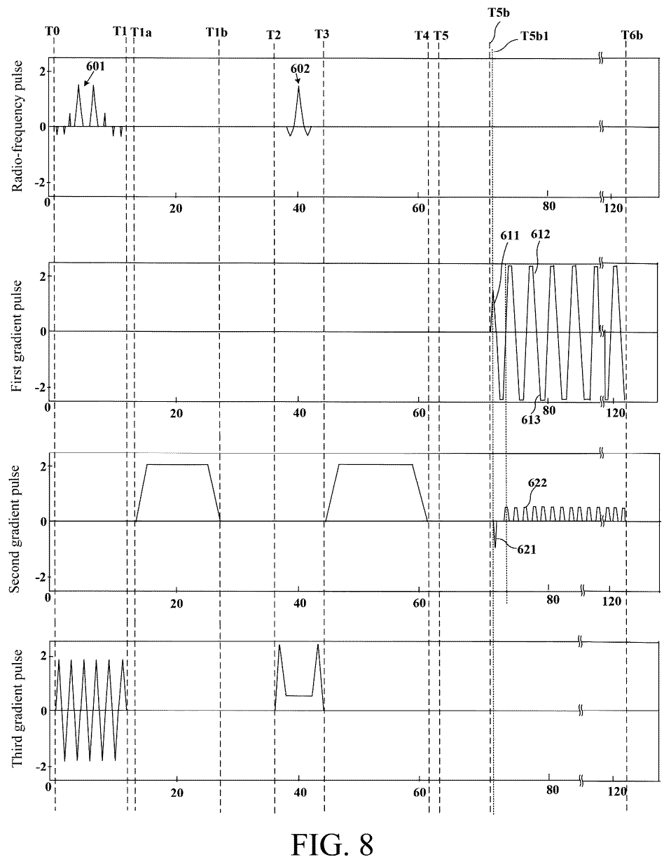

FIG. 8 is a schematic diagram of the third pulse sequence group in Example 2. In FIG. 8, the pulse sequences in the period from T0 to T4 differ from those of FIG. 6 in that: the second gradient pulse is present between T1a and T1b, and between T3 and T4, and is used to apply a diffusion gradient in the second direction to diffuse water molecules. Hence, the third pulse sequence group and the first pulse sequence group have different excitation conditions.

In FIG. 8, T5b to T6b is a data acquisition window of the third pulse sequence group for encoding the MR signals to obtain a data set for image reconstruction. T5b has an offset time TE_{iNEX} with respect to T5, where i=3, so that the offset time is expressed as TE_{3NEX}, and the specific numerical value thereof can be calculated using Formula (1).

The first gradient pulse and the second gradient pulse are present between T5b and T6b.

The first gradient pulse includes a positive-going triangular pulse 611, a positive-going trapezoidal pulse 612, and a negative-going trapezoidal pulse 613, where the start time of the positive-going triangular pulse 611 is T5b.

The second gradient pulse includes a negative-going triangular pulse 621 and a positive-going trapezoidal pulse 622, where the start time of the negative-going triangular pulse 621 is T5b1.

In the above embodiments of the present application, data sets are acquired by offsetting data acquisition windows of different pulse sequence groups in time, and reconstructed images generated from the data sets are synthesized, so that image components generated by fat in the reconstructed images can be canceled out, thereby acquiring a magnetic resonance image in which fat artifacts are suppressed.

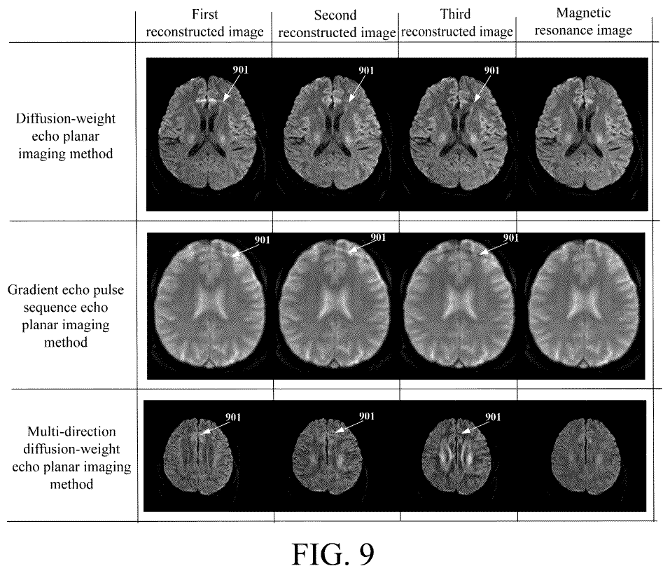

FIG. 9 is a schematic diagram of reconstructed images and magnetic resonance images obtained by applying embodiments of the present application to EPI methods.

The EPI methods shown in FIG. 9 include: a diffusion-weight echo planar imaging (DW EPI) method, a gradient echo pulse sequence echo planar imaging (GRE EPI) method, and a multi-direction diffusion-weight echo planar imaging (multi-direction DW EPI) method.

In the example of FIG. 9, n=3. For each method, FIG. 9 shows a first reconstructed image corresponding to the first pulse sequence group, a second reconstructed image corresponding to the second pulse sequence group, a third reconstructed image corresponding to the third pulse sequence group, and a magnetic resonance image obtained by synthesizing the first reconstructed image, the second reconstructed image and the third reconstructed image.

As shown in FIG. 9, for each method, a fat artifact 901 is present in each of the first reconstructed image, the second reconstructed image, and the third reconstructed image, and in the magnetic resonance image obtained by synthesis, the fat artifact 901 is diminished or disappears. It can be seen that the embodiments of the present application can achieve suppression of fat artifacts in magnetic resonance images.

In addition, the embodiments of the present application may also be combined with other fat artifact suppressing methods, thereby enhancing the effect of fat artifact suppression. The other fat artifact suppressing methods include, for example: chemical shift saturation, slice-selective gradient reversal, short tau inversion recovery (STIR), or spectral-spatial water excitation.

Further provided in the embodiments of the present application is a magnetic resonance image generation apparatus.

FIG. 10 is a schematic diagram of a magnetic resonance image generation apparatus according to an embodiment of the present application. As shown in FIG. 10, the apparatus 1000 includes: a data acquisition unit 1001, configured to acquire at least two data sets using at least two pulse sequence groups, where there is an offset time between data acquisition windows of the respective pulse sequence groups; an image reconstruction unit 1002, configured to respectively generate corresponding reconstructed images according to each of the at least two data sets; and an image synthesis unit 1003, configured to synthesize at least two of the reconstructed images to obtain a magnetic resonance image.

In some embodiments, synthesizing at least two of the reconstructed images includes: averaging amplitudes of the at least two of the reconstructed images to generate the magnetic resonance image.

In some embodiments, at least two among a first gradient pulse, a second gradient pulse, and a third gradient pulse are present in the data acquisition windows.

In some embodiments, the apparatus 1000 further includes: an offset time determination unit 1004, configured to determine the offset time between the data acquisition windows of the respective pulse sequence groups according to the number of groups of the at least two pulse sequence groups and sequence numbers of the respective pulse sequence groups.

In some embodiments, the offset time between the data acquisition windows of two pulse sequence groups with adjacent sequence numbers is inversely proportional to the number of groups.

In some embodiments, the offset time of the data acquisition window of an i-th pulse sequence group with respect to the data acquisition window of a j-th pulse sequence group is proportional to i-j, where i and j are natural numbers greater than or equal to 1 and i is greater than j.

In some embodiments, the at least two pulse sequence groups have identical excitation conditions.

In some embodiments, the directions of diffusion gradients of the at least two pulse sequence groups are different from each other.

For the specific implementation, reference may be made to the foregoing embodiments, which will not be repeated here.

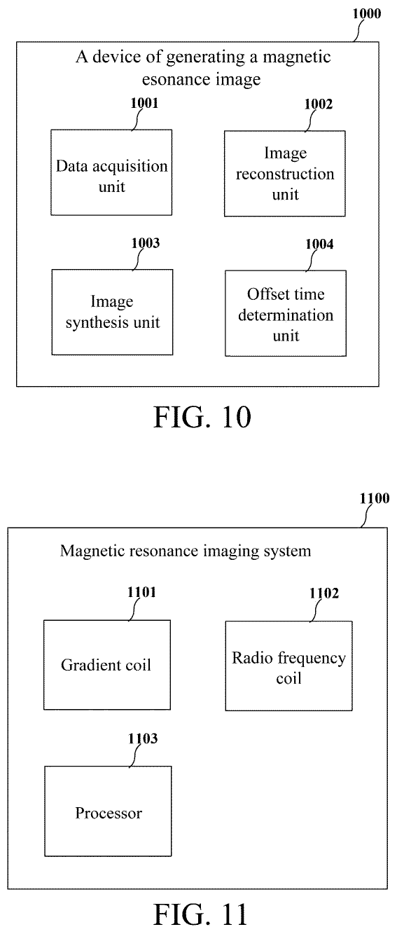

Further provided is a magnetic resonance imaging system 1100, as illustrated in FIG. 11. The system 1100 includes a gradient coil 1101 for generating gradient pulses and a radio-frequency (RF) coil 1102 for generating RF pulses. A processor 1103 is connected to these coils and configured to instruct them to generate the gradient and RF pulses to form at least two pulse sequence groups with offset data acquisition windows, acquire corresponding data sets, generate reconstructed images from each data set, and synthesize at least two of the reconstructed images to obtain a magnetic resonance image.

The concrete composition of the magnetic resonance imaging system is as shown in FIG. 1, and the same content is not repeated herein. The gradient coil 1101 may be, for example, the gradient coil assembly 142 in FIG. 1; the radio-frequency (RF) coil 1102 may be, for example, the RF body coil 148 and/or the RF surface coil 149 in FIG. 1; and the processor 1103 may be, for example, the MRI system controller 130 in FIG. 1.

In some embodiments, the controller 1103 includes a computer processor and a storage medium. The storage medium records a predetermined data processing program to be executed by the computer processor. For example, the storage medium may store a program used to implement scanning processing (e.g., including waveform design/conversion, etc.), image reconstruction, image processing, etc. For example, the storage medium may store a program used to implement the scanning sequence adjusting method for a magnetic resonance imaging system or the magnetic resonance imaging method according to the embodiments of the present application. The specific implementations thereof are as described above, and will not be repeated here.

The described storage medium may include, for example, a ROM, a floppy disk, a hard disk, an optical disk, a magneto-optical disk, a CD-ROM, or a non-volatile memory card.

Further provided in the embodiments of the present application is a computer-readable program, where the program, when executed in an apparatus or an MRI system, causes a computer to execute, in the apparatus or the MRI system, the method according to the foregoing embodiments.

Further provided in the embodiments of the present application is a storage medium having a computer-readable program stored therein, where the computer-readable program causes a computer to execute, in an apparatus or an MRI system, the method according to the foregoing embodiments.

Further provided in the embodiments of the present application is a computer program product at least including a computer program, where the computer program, when executed by a processor, causes an apparatus or an MRI system to execute the method according to the foregoing embodiments.

The above apparatus and method of the present application can be implemented by hardware, or can be implemented by hardware in combination with software. The present application relates to the foregoing type of computer-readable program. When executed by a logic component, the program causes the logic component to implement the foregoing apparatus or constituent components thereof, or causes the logic component to implement the various methods or operations as described above. The present application further relates to a storage medium for storing the above program, such as a hard disk, a disk, an optical disk, a DVD, a flash memory, etc.

The method/apparatus described in view of the embodiments of the present application may be directly embodied as hardware, a software module executed by a processor, or a combination of the two. For example, one or more of the functional block diagrams and/or one or more combinations of the functional block diagrams shown in the drawings may correspond to either respective software modules or respective hardware modules of a computer program flow. These software modules may respectively correspond to the various operations shown in the figures. The foregoing hardware modules can be implemented, for example, by firming the software modules using a field-programmable gate array (FPGA).

The software modules may be located in a RAM, a flash memory, a ROM, an EPROM, an EEPROM, a register, a hard disk, a portable storage disk, a CD-ROM, or any other form of storage medium known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory device, the software modules can be stored in the MEGA-SIM card or the large-capacity flash memory apparatus.

One or more of the functional blocks and/or one or more combinations of the functional blocks shown in the accompanying drawings may be implemented as a general-purpose processor, a digital signal processor (DSP), an application-specific integrated circuit (ASIC), a field-programmable gate array (FPGA) or other programmable logic devices, discrete gate or transistor logic devices, a discrete hardware assembly, or any appropriate combination thereof for implementing the functions described in the present application. The one or more functional blocks and/or the one or more combinations of the functional blocks shown in the accompanying drawings may also be implemented as a combination of computing devices, such as a combination of a DSP and a microprocessor, multiple microprocessors, one or more microprocessors in communication combination with a DSP, or any other such configuration.

The present application is described above with reference to specific embodiments. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A magnetic resonance image generation method, characterized by comprising:
acquiring at least two data sets using at least two pulse sequence groups, wherein there is an offset time between data acquisition windows of the respective pulse sequence groups;
respectively generating corresponding reconstructed images according to each of the at least two data sets; and
synthesizing at least two of the reconstructed images to obtain a magnetic resonance image.

2. The method according to claim 1, wherein,
synthesizing at least two of the reconstructed images comprises:
averaging amplitudes of the at least two of the reconstructed images to generate the magnetic resonance image.

3. The method according to claim 1, wherein,
at least two among a first gradient pulse, a second gradient pulse, and a third gradient pulse are present in the data acquisition windows.

4. The method according to claim 1, further comprising:
determining the offset time between the data acquisition windows of the respective pulse sequence groups according to the number of groups of the at least two pulse sequence groups and sequence numbers of the respective pulse sequence groups.

5. The method according to claim 4, wherein,
the offset time between the data acquisition windows of two pulse sequence groups with adjacent sequence numbers is inversely proportional to the number of groups.

6. The method according to claim 4, wherein,
the offset time of the data acquisition window of an i-th pulse sequence group with respect to the data acquisition window of a j-th pulse sequence group is proportional to i-j, where i and j are natural numbers greater than or equal to 1, and i is greater than j.

7. The method according to claim 1, wherein,
the at least two pulse sequence groups have identical excitation conditions.

8. The method according to claim 1, wherein,
the directions of diffusion gradients of the at least two pulse sequence groups are different from each other.

9. A magnetic resonance image generation apparatus, characterized by comprising:
a data acquisition unit, configured to acquire at least two data sets using at least two pulse sequence groups, wherein there is an offset time between data acquisition windows of the respective pulse sequence groups;
an image reconstruction unit, configured to respectively generate corresponding reconstructed images according to each of the at least two data sets; and
an image synthesis unit, configured to synthesize at least two of the reconstructed images to obtain a magnetic resonance image.

10. The apparatus according to claim 9, wherein,
synthesizing at least two of the reconstructed images comprises:
averaging amplitudes of the at least two of the reconstructed images to generate the magnetic resonance image.

11. The apparatus according to claim 9, wherein,
at least two among a first gradient pulse, a second gradient pulse, and a third gradient pulse are present in the data acquisition windows.

12. The apparatus according to claim 9, further comprising:
an offset time determination unit, configured to determine the offset time between the data acquisition windows of the respective pulse sequence groups according to the number of groups of the at least two pulse sequence groups and sequence numbers of the respective pulse sequence groups.

13. The apparatus according to claim 12, wherein,
the offset time between the data acquisition windows of two pulse sequence groups with adjacent sequence numbers is inversely proportional to the number of groups.

14. The apparatus according to claim 12, wherein,
the offset time of the data acquisition window of an i-th pulse sequence group with respect to the data acquisition window of a j-th pulse sequence group is proportional to i-j, where i and j are natural numbers greater than or equal to 1, and i is greater than j.

15. The apparatus according to claim 9, wherein,
the at least two pulse sequence groups have identical excitation conditions.

16. The apparatus according to claim 9, wherein,
the directions of diffusion gradients of the at least two pulse sequence groups are different from each other.

17. A magnetic resonance imaging system, characterized by comprising:
a gradient coil, configured to generate gradient pulses;
a radio-frequency coil, configured to generate radio-frequency pulses; and
a processor, connected to the gradient coil and the radio-frequency coil, the processor being configured to perform the following:
instructing the gradient coil and the radio-frequency coil to generate the gradient pulses and the radio-frequency pulses, respectively, to form at least two pulse sequence groups, and acquiring at least two data sets according to the at least two pulse sequence groups, wherein there is an offset time between data acquisition windows of the respective pulse sequence groups, the respective pulse sequence groups comprising;
respectively generating corresponding reconstructed images according to each of the at least two data sets; and
synthesizing at least two of the reconstructed images to obtain a magnetic resonance image.
